(19) United States
(12) Patent Application Publication
(10) Pub. No.: US 2012/0124440 A1
(43) Pub. Date: May 17, 2012

(54) LBIST DIAGNOSTIC SCHEME

(76) Inventors: Atchyuth K. Gorti, Austin, TX (US); Vance Threatt, Pflugerville, TX (US); Venkat K. Kuchipudi, Austin, TX (US)

(21) Appl. No.: 12/948,710

(22) Filed: Nov. 17, 2010

(51) Int. Cl. G01R 31/3177; G06F 11/25

(52) U.S. Cl. 714/733; 714/E11.155

(57) ABSTRACT

A method and apparatus to improve the efficiency of debugging a processor is provided. Also provided is a computer readable storage device encoded with data for adapting a manufacturing facility to create an apparatus. The method includes executing a first test pattern from a plurality of test patterns of a logic built-in self test (LBIST). The method further includes generating a first value based on the first test pattern. The method also further includes comparing the first value to a second value, and terminating the LBIST in response to determining that the first value does not equal the second value.

### BACKGROUND

1. Field of the Invention

Embodiments of this invention relate generally to computers, and, more particularly, to a method and apparatus to improve the efficiency of debugging a processor.

2. Description of Related Art

System-on-chip devices (SOCs) are well-known, These devices generally include a processor, one or more modules, bus interfaces, memory devices, and one or more system buses for communicating information. When designing, testing, and checking the SOC, it is useful to operate the SOC in a mode so that problems with programs executing on the SOC can be identified and corrected. This process of problem identification and correction is known as “debugging.” Because multiple modules and their communications occur internally to the chip, access to this information is generally difficult when problems occur in software or hardware. Thus, debugging on these systems is not straightforward. As a result of development of these SOCs, specialized debugging systems have been developed to monitor performance and trace information on the chip. Such systems typically include dedicated hardware or software such as a debug tool and debug software, which accesses a processor through serial communications.

While these debugging methods have been proven effective, they are also time consuming, as many of these methods involve repetitive execution of test cycles. Moreover, it may not be determined that an error was found using these methods until the repetitive execution of test cycles (which sometimes involve tens of thousands of iterations) is complete.

### SUMMARY OF EMBODIMENTS OF THE INVENTION

In one embodiment of the present invention, a method is provided. The method includes executing a first test pattern from a plurality of test patterns of a logic built-in self test (LBIST). The method further includes generating a first value based on the first test pattern. The method also further includes comparing the first value to a second value, and terminating the LBIST in response to determining that the first value does not equal the second value.

In another embodiment of the present invention, an apparatus is provided. The apparatus includes a processor. The processor is configured to execute a first test pattern from a plurality of test patterns of a logic built-in self test (LBIST). The processor is further configured to generate a first value based on the first test pattern. The processor is further configured to compare the first value to a second value, and terminate the LBIST in response to determining that the first value does not equal the second value.

In yet another embodiment of the present invention, a computer readable storage medium encoded with data that, when implemented in a manufacturing facility, adapts the manufacturing facility to create an apparatus, is provided. The apparatus comprises a processor. The processor is configured to execute a first test pattern from a plurality of test patterns of a logic built-in self test (LBIST). The processor is further configured to generate a first value based on the first test pattern. The processor is further configured to compare the first value to a second value, and terminate the LBIST in response to determining that the first value does not equal the second value.

### BRIEF DESCRIPTION OF THE DRAWINGS

The invention may be understood by reference to the following description taken in conjunction with the accompanying drawings, in which the leftmost significant digit(s) in the reference numerals denote(s) the first figure in which the respective reference numerals appear, and in which:

FIG. 1 schematically illustrates a simplified block diagram of a computer system according to one embodiment;

FIG. 2 shows a simplified block diagram of multiple computer systems connected via a network according to one embodiment;

FIG. 3 illustrates an exemplary detailed representation of one embodiment of the central processing unit provided in FIGS. 1-2 according to one embodiment;

FIG. 4 illustrates an exemplary detailed representation of one embodiment of a reset LBIST unit according to one embodiment;

FIG. 5 illustrates a flow chart for performing logic built-in self test (LBIST) operations according to one embodiment of the present invention; and

FIG. 6 illustrates a flow chart for debugging LBIST operations according to one embodiment of the present invention.

While the invention is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but, on the contrary, the intention is to cover all modifications, equivalents, and alternatives falling within the spirit and scope of the invention as defined by the appended claims.

### DETAILED DESCRIPTION

Illustrative embodiments of the invention are described below. In the interest of clarity, not all features of an actual implementation are described in this specification. It will of course be appreciated that in the development of any such actual embodiment, numerous implementation-specific decisions may be made to achieve the developers' specific goals, such as compliance with system-related and business-related constraints, which may vary from one implementation to another. Moreover, it will be appreciated that such a development effort might be complex and time-consuming, but may nevertheless be a routine undertaking for those of ordinary skill in the art having the benefit of this disclosure.

The disclosed subject matter will now be described with reference to the attached figures. Various structures, connections, systems and devices are schematically depicted in the drawings for purposes of explanation only and so as to not obscure the disclosed subject matter with details that are well known to those skilled in the art. Nevertheless, the attached drawings are included to describe and explain illustrative examples of the present invention. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

Generally, the present application describes embodiments of techniques for providing a debugging scheme for logic built-in self test (LBIST) operations, and thereby, improving the efficiency of debugging the processor. Embodiments of the system described herein can immediately detect an error that occurs during LBIST operations without having to wait for the entire set of LBIST test patterns to execute.

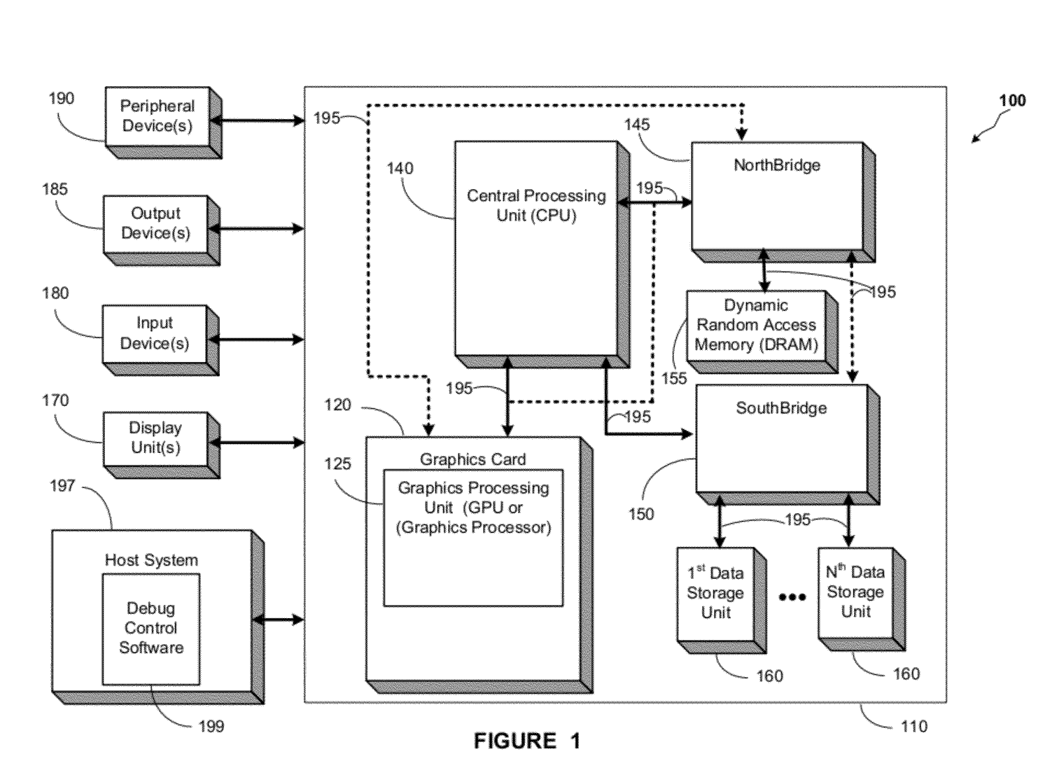

Turning now to FIG. 1, a block diagram of an exemplary computer system 100, in accordance with an embodiment of the present invention, is illustrated. In various embodiments the computer system 100 may be a personal computer, a laptop computer, a handheld computer, a netbook computer, a mobile device, a telephone, a personal data assistant (PDA), a server, a mainframe, a work terminal, or the like. The computer system includes a main structure 110, which may be a computer motherboard, system-on-a-chip, circuit board or printed circuit board, a desktop computer enclosure and/or tower, a laptop computer base, a server enclosure, part of a mobile device, personal data assistant (PDA), or the like. In one embodiment, the main structure 110 includes a graphics card 120. In one embodiment, the graphics card 120 may be an ATI Radeon™ graphics card from Advanced Micro Devices, Inc. (“AMD”) or any other graphics card using memory, in alternate embodiments. The graphics card 120 may, in different embodiments, be connected on a Peripheral Component Interconnect (PCI) Bus (not shown), PCI-Express Bus (not shown) an Accelerated Graphics Port (AGP) Bus (also not shown), or any other connection known in the art. It should be noted that embodiments of the present invention are not limited by the connectivity of the graphics card 120 to the main computer structure 110. In one embodiment, the computer system 100 runs an operating system such as Linux, Unix, Windows, Mac OS, or the like.

In one embodiment, the graphics card 120 may contain a graphics processing unit (GPU) 125 used in processing graphics data. In various embodiments the graphics card 120 may be referred to as a circuit board or a printed circuit board or a daughter card or the like.

In one embodiment, the computer system 100 includes a central processing unit (CPU) 140, which is connected to a northbridge 145. The CPU 140 and the northbridge 145 may be housed on the motherboard (not shown) or some other structure of the computer system 100. It is contemplated that in certain embodiments, the graphics card 120 may be coupled to the CPU 140 via the northbridge 145 or some other connection as is known in the art. For example, the CPU 140, the northbridge 145, and the GPU 125 may be included in a single package or as part of a single die or “chips.” Alternative embodiments that alter the arrangement of various components illustrated as forming part of main structure 110 are also contemplated. In certain embodiments, the northbridge 145 may be coupled to a system RAM (or DRAM) 155; in other embodiments, the system RAM 155 may be coupled directly to the CPU 140. The system RAM 155 may be of any RAM type known in the art; the type of RAM 155 does not limit the embodiments of the present invention. In one embodiment, the northbridge 145 may be connected to a southbridge 150. In other embodiments, the northbridge 145 and the southbridge 150 may be on the same chip in the computer system 100, or the northbridge 145 and the southbridge 150 may be on different chips. In various embodiments, the southbridge 150 may be connected to one or more data storage units 160. The data storage units 160 may be hard drives, solid state drives, magnetic tape, or any other writable media used for storing data. In various embodiments, the central processing unit 140, the northbridge 145, the southbridge 150, the graphics processing unit 125, and/or DRAM 155 may be a computer chip or a silicon-based computer chip, or may be part of a computer chip or a silicon-based computer chip. In one or more embodiments, the various components of the computer system 100 may be operatively, electrically and/or physically connected or linked with a bus 195 or more than one bus 195.

In different embodiments, the computer system 100 may be connected to one or more display units 170, input devices 180, output devices 185, peripheral devices 190 and/or a host system 197. It is contemplated that in various embodiments, these elements may be internal or external to the computer system 100, and may be wired or wirelessly connected, without affecting the scope of the embodiments of the present invention. The display units 170 may be internal or external monitors, television screens, handheld device displays, and the like. The input devices 180 may be any one of a keyboard, mouse, track-ball, stylus, mouse pad, mouse button, joystick, scanner or the like. The output devices 185 may be any one of a monitor, printer, plotter, copier or other output device. The peripheral devices 190 may be any other device that can be coupled to a computer: a CD/DVD drive capable of reading and/or writing to physical digital media, a USB device, Zip Drive, external floppy drive, external hard drive, phone and/or broadband modem, router/gateway, access point and/or the like. The host system 197 may be used to execute debug control software 199 for transferring high-level commands and controlling the extraction and analysis of debug information generated by the CPU 140. The host system 197 and the computer system 100 may be communicatively coupled via a USB link, PCI link, Ethernet link, or any other similar standardized serial port link. To the extent certain exemplary aspects of the computer system 100 are not described herein, such exemplary aspects may or may not be included in various embodiments without limiting the spirit and scope of the embodiments of the present invention as would be understood by one of skill in the art.

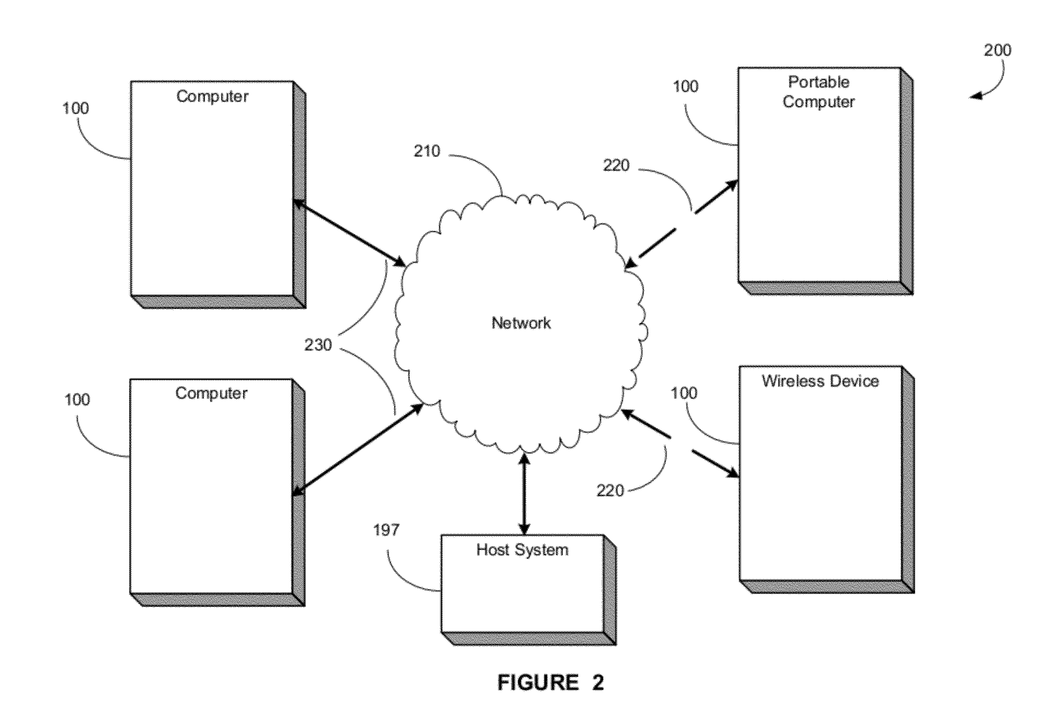

Turning now to FIG. 2, a block diagram of an exemplary computer network 200, in accordance with an embodiment of the present invention, is illustrated. In one embodiment, any number of computer systems 100 and/or host systems 197 may be communicatively coupled and/or connected to each other through a network infrastructure 210. In various embodiments, such connections may be wired 230 or wireless 220 without limiting the scope of the embodiments described herein. The network 200 may be a local area network (LAN), wide area network (WAN), personal network, company intranet or company network, the Internet, or the like. In one embodiment, the computer systems 100 that are connected to the network 200 via network infrastructure 210 may be a personal computer, a laptop computer, a netbook computer, a handheld computer, a mobile device, a telephone, a personal data assistant (PDA), a server, a mainframe, a work terminal, or the like. The number of computers depicted in FIG. 2 is exemplary in nature; in practice any number of computer systems 100 maybe coupled/connected using the network 200.

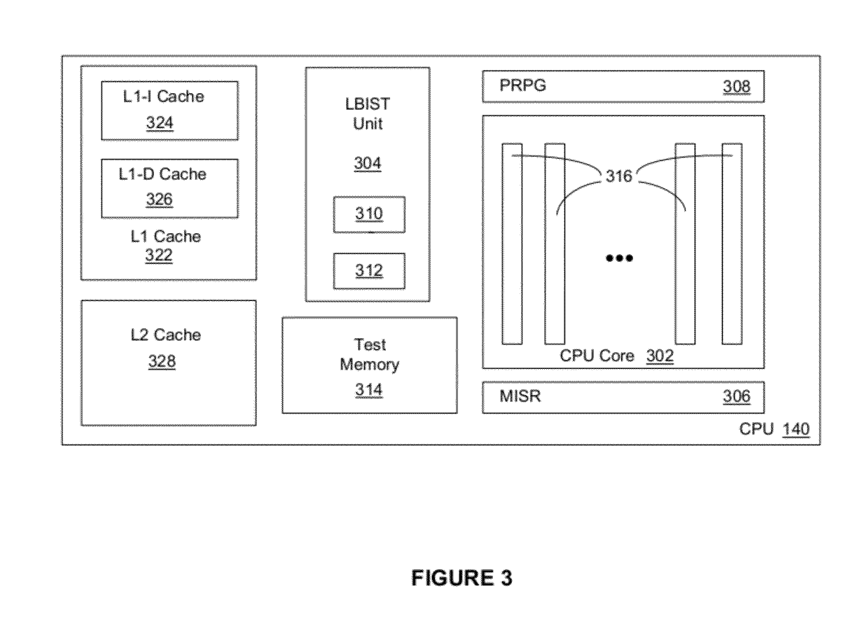

Turning now to FIG. 3, a diagram of an exemplary implementation of a processor, CPU 140, in accordance with an embodiment of the present invention, is illustrated. The CPU 140 includes a CPU core 302. The CPU core 302 may be used to execute instructions and/or manipulate data stored in the memory 155 (shown in FIG. 1). The CPU 140 also implements a hierarchical (or multilevel) cache system that may be used to speed access to the instructions and/or data by storing selected instructions and/or data in the caches. However, persons of ordinary skill in the art having benefit of the present disclosure should appreciate that alternative embodiments of the computer system 100 may implement different configurations of the CPU 140, such as configurations that use external caches.

The illustrated cache system includes a level 2 (L2) cache 328 for storing copies of instructions and/or data that are stored in the main memory 155. In the illustrated embodiment, the L2 cache 328 is 16-way associative to the main memory 155 so that each line in the main memory 155 can potentially be copied to and from 16 particular lines (which are conventionally referred to as “ways”) in the L2 cache 328. However, persons of ordinary skill in the art having benefit of the present disclosure should appreciate that alternative embodiments of the main memory 155 and/or the L2 cache 328 can be implemented using any associativity. Relative to the main memory 155, the L2 cache 328 may be implemented using smaller and faster memory elements. The L2 cache 328 may also be deployed logically and/or physically closer to the CPU core 302 (relative to the main memory 155) so that information may be exchanged between the CPU core 155 and the L2 cache 328 more rapidly and/or with less latency.

The illustrated cache system also includes an L1 cache 322 for storing copies of instructions and/or data that are stored in the main memory 155 and/or the L2 cache 328. Relative to the L2 cache 328, the L1 cache 324 may be implemented using smaller and faster memory elements so that information stored in the lines of the L1 cache 324 can be retrieved quickly by the CPU 140. The L1 cache 324 may also be deployed logically and/or physically closer to the CPU core 302 (relative to the main memory 155 and the L2 cache 328) so that information may be exchanged between the CPU core 302 and the L1 cache 324 more rapidly and/or with less latency (relative to communication with the main memory 155 and the L2 cache 328). Persons of ordinary skill in the art having benefit of the present disclosure should appreciate that the L1 cache 322 and the L2 cache 328 represent one exemplary embodiment of a multi-level hierarchical cache memory system. Alternative embodiments may use different multilevel caches including elements such as L0 caches, L1 caches, L2 caches, L3 caches, and the like.

In the illustrated embodiment, the L1 cache 322 is separated into level 1 (L1) caches for storing instructions and data, which are referred to as the L1-I cache 324 and the L1-D cache 326. Separating or partitioning the L1 cache 322 into an L1-I cache 324 for storing only instructions and an L1-D cache 326 for storing only data may allow these caches to be deployed closer to the entities that are likely to request instructions and/or data, respectively. Consequently, this arrangement may reduce contention, wire delays, and generally decrease latency associated with instructions and data. In one embodiment, a replacement policy dictates that the lines in the L1-I cache 324 are replaced with instructions from the L2 cache 328 and the lines in the L1-D cache 326 are replaced with data from the L2 cache 328. However, persons of ordinary skill in the art should appreciate that alternative embodiments of the L1 cache 322 may not be partitioned into separate instruction-only and data-only caches 324, 326. The caches 322, 324, 326, 328 can be flushed by writing back modified (or “dirty”) cache lines to the main memory 155 and invalidating other lines in the caches 322, 324, 326, 328.

The CPU 140 may also include an LBIST unit 304, a multiple input signature register (MISR) 306, a pseudorandom pattern generator (PRPG) 309, and a test memory 314. The LBIST unit 304 may include an LBIST controller 310,. The LBIST controller 310 may scan in a plurality of pseudorandom patterns of bits (i.e., patterns), generated by the PRPG 308, into a plurality of scan chains 316, which are connected to various logic within the CPU core 302. Accordingly, the patterns may be propagated through the logic of the CPU core 302. The outputs of the logic are subsequently captured into the plurality of scan chains 316. This test cycle may be repeated many times (e.g. 10,000 iterations). In one embodiment, the results of each pattern may be combined in some manner with the results of the previous pattern to form a signature (e.g. a cyclic redundancy check (CRC) signature). The resulting signature may be stored in the MISR 306. The LBIST controller 310 may compare the resulting signature with a predetermined signature value of a correctly functioning CPU core 302 (e.g. as determined during the simulation of the CPU core 302). If the signature value matches, then it may be determined that the CPU core 302 is functioning properly. On the other hand, if the signature value does not match, then it may be determined that the CPU core 302 is not functioning normally.

In another embodiment, a signature value may be generated and stored for each pattern executed. Each signature value may be stored in the test memory 314. In one embodiment, the test memory 314 may be a non-volatile memory (e.g., an EPROM, EEPROM, flash memory, and the like). After a particular pattern is executed, the generated signature value may be compared to a predetermined signature value that is determined when a corresponding pattern is executed during simulation. In another embodiment, a portion of the generated signature value may be generated and stored for each pattern executed. In this case, the portion of the generated signature value may be compared to a corresponding portion of the predetermined signature value that is determined when a corresponding pattern is executed during simulation. In doing so, the size of the test memory 314 may be reduced (as compared to storing the entire signature value). In yet another embodiment, at least one or more parity bits that are generated based on the signature value generated for each pattern executed may be stored in the test memory 314. In this case, the at least one or more parity bits that are generated may be compared to a predetermined at least one or more parity bits that are determined when a corresponding pattern is executed during simulation. The size of the test memory 314 may also be reduced in this case, as the entire signature value is not stored in the test memory 314.

In the event that a mismatch is found, the LBIST controller 310 may terminate LBIST operations. Performing iterative comparisons of signature values allows the LBIST controller 310 to terminate early without having to wait for the entire set of patterns to complete. In doing so, the debug time of the CPU core 302 is decreased.

The LBIST unit 304 may also include an interface 312 for facilitating with testing and debugging of LBIST operations. The host system 197 (illustrated in FIG. 1) may perform debug operations by communicating with the LBIST unit 304 using the interface 312. In one embodiment, the interface 312 may include an IEEE-1149.1 compliant JTAG interface. In this case, the host system 197 may also include an IEEE-1149.1 compliant JTAG interface to communicate with the LBIST unit 304.

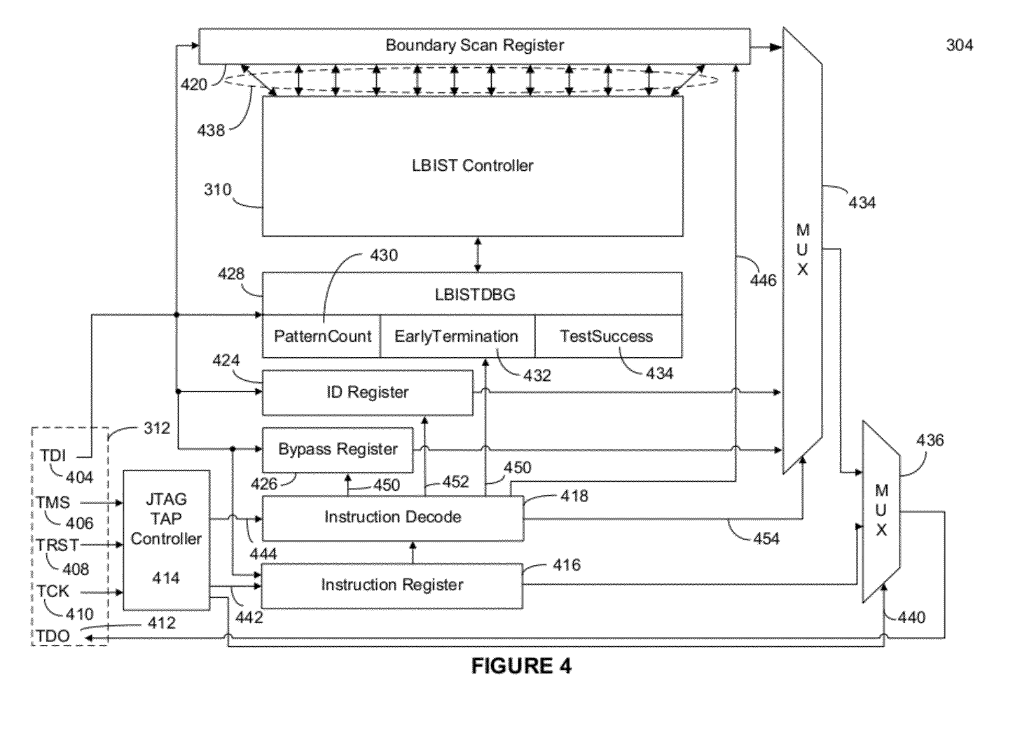

Turning now to FIG. 4, a block diagram of the LBIST unit 304, in accordance with an embodiment of the present invention, is illustrated. The MIST unit 304 includes an LBIST controller 310, a JTAG interface 312, a JTAG test access port (TAP) controller 414, an instruction register 416, an instruction decode unit 418, standardized HAG data registers (a boundary-scan register 420, ID register 424, and bypass register 426), and a user-defined test data register (LBIST Debug Register (LBISTDBG 428)). The JTAG interface 312 includes IEEE 1149.1 JTAG-compliant input and output signals including a mode signal (TMS) 406, a test clock (TCK) 410, a test data input (TDI) 404, a test data output (TDO) 412, and a test reset input (TRST) 408.

The TDI signal 404 may function as the serial data input to all the registers (e.g., the instruction register 416, the boundary scan register 420, the ID register 424. the bypass register 426 and the LBISTDBG register 428). The state of the JTAG TAP controller 414 and the instruction loaded into the instruction register 416 may determine which data register (e.g. the boundary scan register 420, the ID register 424, the bypass register 426 and the LBISTDBG register 428) is fed by the TDI signal 404 for any given operation. The TDO signal 412 is the serial data output for all the registers 416, 420, 424, 426, 428. The state of the JTAG TAP controller 414 and the instruction loaded into the instruction register 416 may determine which register 416, 420, 424, 426, 428 feeds the TDO signal 412 for a specific operation. The output signals of the data registers 416, 420, 424, 426, 428 may be selectively coupled to an output multiplexer 436 through a register selector multiplexer 434 and are ultimately transferred to the host controller 197 (illustrated in FIG. 1) through the TDO signal 412.

Referring still to FIG. 4, the boundary scan register 420 may peg snit control and observation of various internal logic signals of the LBIST controller 310 and/or the data registers 420, 424, 426, 428. When a proper instruction (e.g. the IEEE 1149.1-defined INTEST instruction) is loaded into the instruction register 416, the boundary scan register 420 may capture values from the various internal signals from within the LBIST controller 310 and/or the data registers 420, 424, 426, 428 via bus 438. The values of the boundary scan register 420 may then be shifted out back to host controller 197 (shown in FIG. 1) for debug. The bypass register 122 may be a single-bit register that passes information from the TDI input 404 to the TDO output 412. Generally, the bypass register 426 allows other devices (not shown) that are also connected to a JTAG interface (not shown) to be tested in a scan path configuration.

The LBISTDBG register 42$ may be used to determine if LBIST operations have terminated early. The LBISTDBG register 428 may be read by the host system 197 using a user-defined instruction. The LBISTDBG register 428 may contain three fields: a PatternCount field 430, an EarlyTermination field 432, and a TestSuccess field 434. The PatternCount field 430 may contain a value indicating the pattern number for which the LBIST controller 310 has terminated. For example, the PatternCount field 430 having a value of 1000 would indicate that LBIST operations have terminated on pattern number 1000. The PatternCount field 430 may be incremented after each pattern is executed. In one embodiment, the PatternCount field 430 may also be programmed, via the host system 197, with a pattern number from which to start the testing. For example, if the a value of 2000 is programmed into the PatternCount field 430, then the LBIST controller 310 may begin testing at pattern 2000.

The EarlyTermination field 432 may contain a bit (i.e. a termination bit) that is indicative of whether or not LBIST operations have terminated. For example, the bit may be set to a value ‘1’ if the LBIST operations terminated early. In one embodiment, the EarlyTermination field 432 may be polled by the host server 197 until the termination bit is set to a value of ‘1.’ In another embodiment, an interrupt to the host system 197 may be asserted upon the termination bit being set. Upon detection of the termination bit being set to ‘1’, it may he determined that the LBIST controller 310 has found an error within logic of the CPU core 302. Moreover, because the pattern number is stored in the PatternCount field 430, it may also be determined which pattern caused the error by reading the PatternCount field 430.

The TestSuccess field 432 may contain a bit (i.e. a success bit), which when set, indicates that LBIST operations have successfully completed (i.e., no errors were found). In one embodiment, the TestSuccess field 432 may he polled by the host server 197 until the success bit is set to a value of ‘1.’ In another embodiment, an interrupt to the host system 197 may be asserted upon the success bit being set. Upon detection of the success bit being set to ‘1’, it may be determined that the LBIST controller did not find any errors within logic of the CPU core 302.

Referring still to FIG. 4, the JTAG TAP controller 414 may he controlled by the host system 197 via the TCK 410, TMS 406, and TRST 408 control signals to generate control signals 440, 442, 444 for the output multiplexer 436, the instruction register 416, and the instruction decoder circuit 418, which is connected to receive instructions from the instruction register 416. In response, the instruction decoder circuit 418 may generate control signals 446, 448, 450, 452 for the data registers 420, 424, 426, 428 and a control signal 454 for the register selector multiplexer 128.

The JTAG TAP controller 414 may be implemented as a finite state machine (FSM), which, depending on the inputs applied, controls the instruction and data storing/loading operations of the instruction register 416 and the data registers 420, 424, 426, 428. As a FSM, the JTAG TAP controller 414 utilizes various inputs to sequence through the various states of the FSM to achieve specific functions. Specifically, the JTAG TAP controller 414 utilizes the TMS signal 406 and the TCK signal 410 to transition between the various states of the JTAG TAP controller 414. The TRST signal 408 may be used to reset the reset and initialization state machine 311. The TMS signal 406 functions as a mode input signal to the JTAG TAP controller 414. At the rising edge of the TCK signal 410, the TMS signal 406 determines the sequence of the HAG TAP controller 414, The TCK 410 signal provides the clock sequences to the JTAG TAP controller 414, as well as all the registers 416, 420, 424,426, 428.

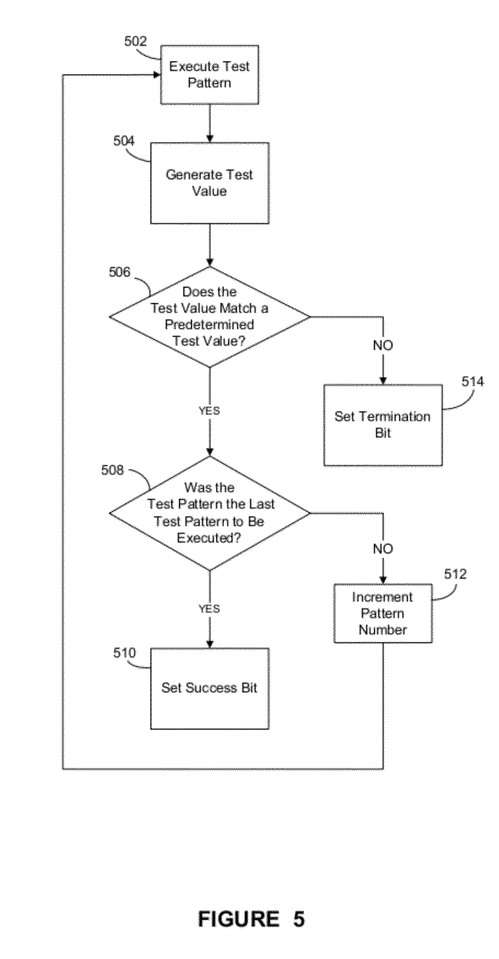

Turning now to FIG. 5, a flowchart for performing LBIST operations, in accordance with an embodiment of the present invention, is illustrated. The operations begin at the block 502, where the first test pattern is executed. After the test pattern has propagated throughout the logic of the CPU core 302, a test value is generated at the block 504. In one embodiment, the test value may be a signature value. In another embodiment, the test value may be a portion of the signature value. In yet another embodiment, the test value may be at least one or more parity bits, which are calculated based on the signature value generated as a result of the test pattern executed. At the block 506, it is determined whether or not the signature value matches a predetermined signature value (i.e. the signature value calculated during simulation of the CPU core 302 for the particular test pattern). If the signature values match, then the operations continue to the block 508, where it is determined if the test pattern executed was the last test pattern to be executed. If it is determined that the last pattern was executed, then at the block 510, the success bit is set, thereby indicating that the LBIST operations completed without finding an error. However, if it determined that the last pattern was not executed, the pattern number in the PatternCount field 430 of the LBISTDBG register 428 is incremented at the block 512, and the operations return to the block 502, where the next pattern is executed. Returning to the block 506, if it is determined that the signature values do not match, then at the block 514, the termination bit is set, thereby indicating that the LBIST controller 310 has found an error and terminated early.

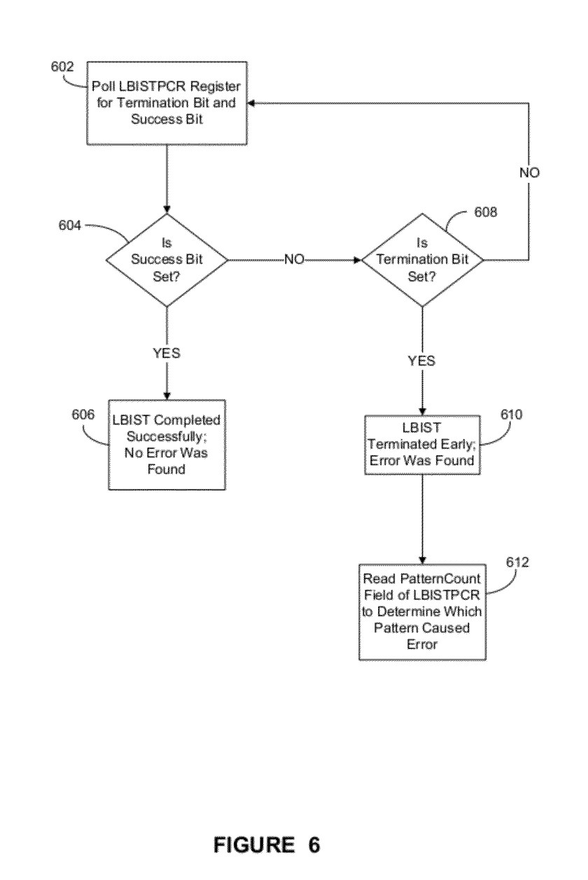

Turning now to FIG. 6, a flowchart for debugging the LBIST operations, in accordance with an embodiment of the present invention, is illustrated. The operations begin at the block 602, where the TestSuccess field 434 and the EarlyTermination field 432 of the LBISTDBG register 428 are polled. At the block 604, it is determined whether or not the success bit stored in the TestSuccess field 432 is set. If the success bit is set, then at the block 606, it may be determined that all the test patterns have executed and no error was found. On the other hand, if the success bit is not set, then at the block 608, it is determined whether or not the termination bit stored in the EarlyTermination field 432 is set. If the termination bit is set, then at the block 610 it may be determined that the LBIST terminated early, and therefore, an error was found within the logic of the CPU core 302. Subsequently, at the block 612, the host system 197 may read out the pattern number causing the error from the PatternCount field 430 of the LBISTDBG register 428. However, if the termination bit is not set, then the operations return to the block 602, where the TestSuccess field 434 and the EarlyTermination field 432 are polled.

It is also contemplated that, in some embodiments, different kinds of hardware descriptive languages (HDL) may be used in the process of designing and manufacturing very large scale integration circuits (VLSI circuits) such as semiconductor products and devices and/or other types semiconductor devices. Some examples of HDL are VHDL and Verilog/Verilog-XL, but other HDL formats not listed may be used. In one embodiment, the HDL code (e.g., register transfer level (RTL) code/data) may be used to generate GDS data, GDSII data and the like. GDSII data, for example, is a descriptive file format and may be used in different embodiments to represent a three-dimensional model of a semiconductor product or device. Such models may be used by semiconductor manufacturing facilities to create semiconductor products and/or devices. The GDSII data may be stored as a database or other program storage structure. This data may also be stored on a computer readable storage device (e.g., data storage units 160, RAMs 130 & 155, compact discs, DVDs, solid state storage and the like). In one embodiment, the GDSII data (or other similar data) may be adapted to configure a manufacturing facility (e.g., through the use of mask works) to create devices capable of embodying various aspects of the instant invention. In other words, in various embodiments, this GDSII data (or other similar data) may be programmed into a computer 100, processor 125/140 or controller, which may then control, in whole or part, the operation of a semiconductor manufacturing facility (or fab) to create semiconductor products and devices.

It should also be noted that while various embodiments may be described in terms of memory storage for graphics processing, it is contemplated that the embodiments described herein may have a wide range of applicability, not just for graphics processes, as would be apparent to one of skill in the art having the benefit of this disclosure.

The particular embodiments disclosed above are illustrative only, as the invention may be modified and practiced in different but equivalent manners apparent to those skilled in the art having the benefit of the teachings herein. Furthermore, no limitations are intended to the details of construction or design as shown herein, other than as described in the claims below. It is therefore evident that the particular embodiments disclosed above may be altered or modified and all such variations are considered within the scope and spirit of the claimed invention.

Accordingly, the protection sought herein is as set forth in the claims below.

What is claimed:

1. A method comprising:
executing a first test pattern from a plurality of test patterns of a logic built-in self test (LBIST);
generating a first value based on the first test pattern;
comparing the first value to a second value; and
terminating the LBIST in response to determining that the first value does not equal the second value.

2. The method of claim 1, further comprising:
executing a second test pattern from the plurality of test patterns of the LBIST in response to determining that the first value equals the second value.

3. The method of claim 1, further comprising:
setting a termination bit in response to terminating the LBIST.

4. The method of claim 1, wherein the first value is a signature value, and wherein the second value is a signature value stored in a test memory.

5. The method of claim 1, wherein the first value is a portion of a signature value, wherein the second value is a portion of a signature value, and wherein the second value is stored in a test memory.

6. The method of claim 1, wherein the first value is a group of one or more parity bits generated based on a signature value, wherein the second value is a predetermined group of one or more parity bits generated based on a predetermined signature value, and wherein the second value is stored in a test memory.

7. The method of claim 1, wherein a test memory stores a corresponding value for each of the plurality of test patterns of the LBIST.

8. An apparatus, comprising:
a processor configured to:
execute a first test pattern from a plurality of test patterns of a logic built-in self test (LBIST);
generate a first value based on the first test pattern;
compare the first value to a second value; and
terminate the LBIST in response to determining that the first value does not equal the second value.

9. The apparatus of claim 8, wherein the processor is further configured to:
execute a second test pattern from the plurality of test patterns of the LBIST in response to determining that the first value equals the second value.

10. The apparatus of claim 8, wherein the first value is a signature value, and wherein the second value is a predetermined signature value stored in a test memory.

11. The apparatus of claim 8, wherein the first value is a portion of a signature value, wherein the second value is a portion of a signature value, and wherein the second value is stored in a test memory.

12. The apparatus of claim 8, wherein the first value is a group of one or more parity bits generated based on a signature value, wherein the second value is a group of one or more parity bits generated based on a signature value, and wherein the second value is stored in a test memory.

13. The apparatus of claim 8, wherein a test memory stores a corresponding value for each of the plurality of test patterns of the LBIST.

14. A computer readable storage medium encoded with data that, when implemented in a manufacturing facility, adapts the manufacturing facility to create an apparatus, the apparatus comprising:
a processor configured to:
execute a first test pattern from a plurality of test patterns of a logic built-in self test (LBIST);
generate a first value based on the first test pattern;
compare the first value to a second value; and
terminate the LBIST in response to determining that the first value does not equal the second value.

15. The computer readable storage medium of claim 16, wherein the processor is further configured to:
execute a second test pattern from the plurality of test patterns of the LBIST in response to determining that the first value equals the second value.

16. The computer readable storage medium of claim 16, wherein the first value is a signature value, and wherein the second value is a signature value stored in a test memory.

17. The computer readable storage medium of claim 16, wherein the first value is a portion of the signature value, wherein the second value is a portion of a signature value, and wherein the second value is stored in a test memory.

18. The computer readable storage medium of claim 16, wherein the first value is a group of one or more parity bits generated based on a signature value, wherein the second value is a group of one or more parity bits generated based on a signature value, and wherein the second value is stored in a test memory.

19. The computer readable storage medium of claim 16, wherein a test memory stores a corresponding value for each of the plurality of test patterns of the LBIST.

20. The computer readable storage medium of claim 16, wherein the processor is further configured to:
set a termination bit in response to terminating the LBIST
